(19) United States
(12) Patent Application Publication
(10) Pub. No.: US 2016/0079264 A1
(43) Pub. Date: Mar. 17, 2016

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventor: Merii INABA, Kamakura (JP)

(73) Assignee: Kabushiki Kaisha Toshiba, Minato-ku (JP)

(21) Appl. No.: 14/645,765

(22) Filed: Mar. 12, 2015

(30) Foreign Application Priority Data
Sep. 12, 2014 (JP) 2014-186655

(51) Int. Cl. H01L 27/115; H01L 21/3213; H01L 21/311

(52) U.S. Cl. CPC H01L 27/11582; H01L 21/31116; H01L 21/32135

(57) ABSTRACT

According to one embodiment, a stacked body including electrode layers and first insulating layers; first semiconductor members extending in the stacked body; a second semiconductor member including first portions and a second portion, the second semiconductor member being connected commonly to lower ends of the first semiconductor members; a memory film provided between a first electrode layer of the first electrode layers and one of the first semiconductor members; and an insulating film provided between the second semiconductor member and the stacked body. A second electrode layer of the electrode layers is provided on the second portion of the second semiconductor member via the insulating film. A third electrode layer of the electrode layers is provided under the second portion of the second semiconductor member via the insulating film. One of the first insulating layers is provided between the second electrode layer and the third electrode layer.

### CROSS-REFERENCE TO RELATED APPLICATIONS

This application is based upon and claims the benefit of priority from Japanese Patent Application No. 2014-186655, filed on Sep. 12, 2014; the entire contents of which are incorporated herein by reference.

### FIELD

Embodiments described herein relate to a nonvolatile semiconductor memory device and a method for manufacturing the same.

### BACKGROUND

There is a nonvolatile semiconductor memory device in which holes are made in a stacked body including alternately-stacked control gate electrodes and insulating layers, a memory film is formed on side walls of the holes, and a channel body layer is further formed inside the holes. The channel body layer includes a pair of columnar portions, and a linking portion that links the pair of columnar portions.

However, when making the holes for forming the columnar portions, components of the lower layer of the stacked body may re-adhere to the hole walls in the etching in the case where the lower layer is a single layer and/or the material of the lower layer is different from the material of the stacked body recited above. Thereby, there are cases where the lower portions of the holes have tapered configurations and the diameters of the lower portions of the holes are not the target diameter. When the channel body layers are provided inside holes in such a state, the configurations of the channel body layers inside the holes may not be good.

### BRIEF DESCRIPTION OF THE DRAWINGS

FIG. 1A and FIG. 1B are schematic cross-sectional views showing a nonvolatile semiconductor memory device according to a first embodiment;

FIG. 2 is a circuit diagram showing a memory string included in the nonvolatile semiconductor memory device according to the first embodiment;

FIG. 3A and FIG. 3B are schematic cross-sectional views showing the nonvolatile semiconductor memory device according to the first embodiment;

FIG. 4A to FIG. 6B are schematic cross-sectional views showing a manufacturing processes of the nonvolatile semiconductor memory device according to the first embodiment;

FIG. 7 is a schematic cross-sectional view showing a manufacturing process of a nonvolatile semiconductor memory device according to a first reference example;

FIG. 8A is a schematic cross-sectional view showing a nonvolatile semiconductor memory device according to a second reference example and FIG. 8B is a schematic plan view showing the nonvolatile semiconductor memory device according to the second reference example;

FIG. 9A is a schematic cross-sectional view showing the nonvolatile semiconductor memory device according to the first embodiment and FIG. 9B is a schematic plan view showing the nonvolatile semiconductor memory device according to the first embodiment; and

FIG. 10 is a schematic cross-sectional view showing a nonvolatile semiconductor memory device according to a second embodiment.

### DETAILED DESCRIPTION

In general, according to one embodiment, a nonvolatile semiconductor memory device, includes: a stacked body provided on a foundation layer, the stacked body including electrode layers stacked alternately with first insulating layers; first semiconductor members extending in a stacking direction of the stacked body, the first semiconductor members being provided in the stacked body; a second semiconductor member provided under the first semiconductor members, the second semiconductor member including first portions extending in the stacking direction and a second portion extending in a direction crossing the stacking direction, the first portions and the second portion being provided in the stacked body, the second semiconductor member being connected commonly to lower ends of the first semiconductor members; a memory film provided between a first electrode layer of the electrode layers and one of the first semiconductor members; and an insulating film provided between the second semiconductor member and the stacked body. A second electrode layer of the electrode layers is provided on an upper surface of the second portion of the second semiconductor member via the insulating film. A third electrode layer of the electrode layers is provided under a lower surface of the second portion of the second semiconductor member via the insulating film.

Embodiments will now be described with reference to the drawings. In the description hereinbelow, the same members are marked with the same reference numerals; and a description is omitted as appropriate for members once described.

### First Embodiment

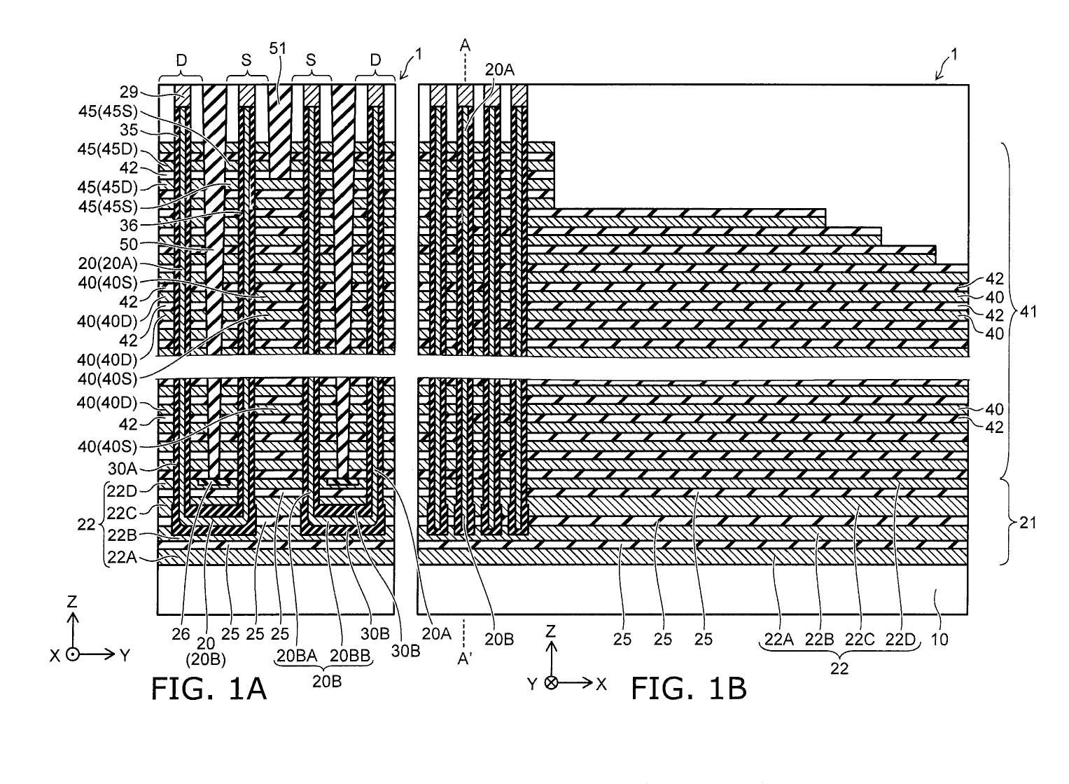

FIG. 1A and FIG. 1B are schematic cross-sectional views showing a nonvolatile semiconductor memory device according to a first embodiment.

A cross section along line A-A′ of FIG. 1B is shown in FIG. 1A.

For convenience of description in the embodiment, an XYZ orthogonal coordinate system is introduced in the drawings. In the coordinate system, two mutually-orthogonal directions parallel to a major surface of a foundation layer 10 are taken as an X-direction and a Y-direction; and a direction orthogonal to both the X-direction and the Y-direction is taken as a Z-direction.

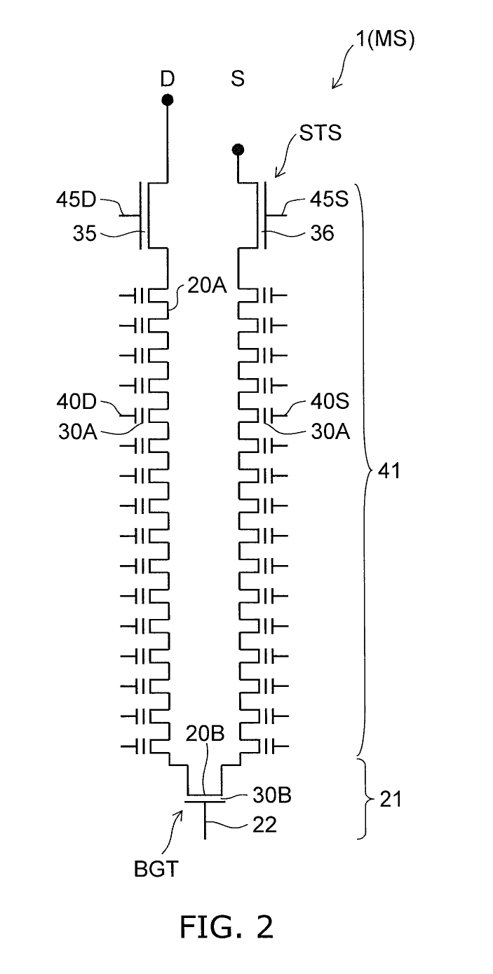

FIG. 2 is a circuit diagram showing a memory string included in the nonvolatile semiconductor memory device according to the first embodiment.

The nonvolatile semiconductor memory device 1 is a NAND nonvolatile memory that can freely and electrically erase and program data and retain the memory content even when the power supply is OFF. The nonvolatile semiconductor memory device 1 shown in FIGS. 1A and 1B is normally called BiCS (Bit Cost Scalable) flash memory.

In the nonvolatile semiconductor memory device 1, a stacked body 21 is provided on the foundation layer 10; and a stacked body 41 is provided on the stacked body 21.

The foundation layer 10 is, for example, an insulating layer and a semiconductor layer such as a silicon substrate, etc. Active elements such as transistors, etc., passive elements such as resistors, capacitors, etc., may be provided in the foundation layer 10.

The stacked body 21 is provided between the foundation layer 10 and the stacked body 41. The stacked body 21 includes a back gate 22. The back gate 22 is, for example, a layer including polysilicon (Si) to which an impurity element is added. The back gate 22 includes multiple electrode layers; and in the example shown in FIGS. 1A and 1B, the back gate 22 includes electrode layers 22A, 22B, 22C, and 22D.

An insulating layer 25 is provided in each space between the electrode layers 22A to 22D. The insulating layer 25 includes, for example, silicon oxide. The stacked body 21 is formed of the electrode layer 22A/insulating layer 25/electrode layer 22B/insulating layer 25/electrode layer 22C/insulating layer 25/electrode layer 22D. The number of layers included in the stacked body 21 is not limited to the example shown in FIGS. 1A and 1B.

For example, the three-layer structure of the electrode layer/insulating layer/electrode layer described above is the minimum unit of the stacked body 21; and the stacked body 21 may have a stacked structure of the seven layers described above, less than the seven layers described above, or more than the seven layers described above.

In the stacked body 41, multiple electrode layers 40 and multiple insulating layers 42 are stacked alternately in the Z-direction. The multiple electrode layers 40 include electrode layers 40D on the drain (D) side and electrode layers 40S on the source (S) side. The electrode layers 40 are, for example, conductive layers including silicon to which an impurity element such as boron (B) or the like is added. The electrode layers 40 may be called word lines. The insulating layers 42 are provided between the electrode layers 40 above and below. The insulating layers 42 include, for example, silicon oxide. The number of electrode layers 40 and the number of insulating layers 42 are not limited to the numbers illustrated.

The electrode layers 40D and the electrode layers 40S are positioned at the same height from the foundation layer 10. The electrode layers 40D and the electrode layers 40S are separated by an insulating layer 50 in the Y-direction. The insulating layer 50 is provided inside the stacked body 41 between a pair of channel body layers 20A (first semiconductor member). The insulating layer 50 extends in the stacking direction of the stacked body 41 (the Z-direction). The insulating layer 50 reaches the stacked body 21 on the lower side of the stacked body 41. The lower end of the insulating layer 50 is connected to an insulating layer 26 provided inside the stacked body 21. The insulating layer 26 is provided in the electrode layer 22D, for example.

Multiple selection gate electrodes 45 are provided in the upper portion of the stacked body 41. The selection gate electrodes 45 are, for example, conductive layers including silicon to which an impurity is added. The selection gate electrodes 45 include selection gate electrodes 45D on the drain side and selection gate electrodes 45S on the source side. The insulating layer 50 or an insulating layer 51 is provided between the selection gate electrodes 45 adjacent to each other in the Y-direction.

The period of the electrode layers 40 and the insulating layers 42 arranged alternately in the Z-direction may be the same as or different from the period of the electrode layers and the insulating layers 25 arranged alternately in the Z-direction in the back gate 22.

Contact electrodes (not shown) are connected to the multiple electrode layers 40 and the multiple selection gate electrodes 45; and a prescribed potential is supplied to each of the contact electrodes from a peripheral circuit.

A pair of channel body layers 20A is provided inside the stacked body 41. The pair of channel body layers 20A extends in the stacked body 41 in the stacking direction of the stacked body 41 (the Z-direction) and reaches the stacked body 21 on the lower side of the stacked body 41. A memory film 30A is provided between the multiple electrode layers 40 and the pair of channel body layers 20A.

For example, the memory film 30A has an ONO (Oxide-Nitride-Oxide) structure in which a silicon nitride film is interposed between silicon oxide films. For example, a charge storage film is provided between a silicon oxide film contacting the electrode layers 40 and a silicon oxide film contacting the channel body layer 20A. The charge storage film includes, for example, silicon nitride.

One of the pair of channel body layers 20A is electrically connected to a bit line (not shown) via a contact electrode 29; and the other of the pair of channel body layers 20A is electrically connected to a source line (not shown) via the contact electrode 29.

A channel body layer 20B (second semiconductor member) is provided inside the stacked body 21 under the channel body layer 20A. The material of the channel body layer 20B is the same as the material of the channel body layer 20A. The channel body layer 20B includes columnar portions 20BA which extends in the stacked body 21 in the Z-direction and a linking portion 20BB which extends the stacked body 21 in a direction crossing the Z direction. The channel body layer 20B is commonly connected to the lower ends of the pair of channel body layers 20A. The lower ends of the pair of channel body layers 20A are electrically connected to each other by the channel body layer 20B. The channel body layer 20B is not limited to being connected to the pair of channel body layers 20A (described below).

In other words, the nonvolatile semiconductor memory device 1 includes a channel body layer 20 having a U-shaped configuration in which the channel body layers 20A and the channel body layer 20B are formed as one body. The channel body layer 20 is, for example, a layer including silicon. Other than the rod configuration as illustrated, the channel body layer 20 may have a tubular configuration.

An insulating film 30B is provided between the channel body layer 20B and the stacked body 21. The insulating film 30B may be formed simultaneously with the memory film 30A. For example, the insulating film 30B has an ONO structure. A portion of the electrode layer 22D of the uppermost layer of the multiple electrode layers 22A to 22D and a portion of the electrode layer 22C under the electrode layer 22D are provided between the channel body layer 20B and the insulating layer 50. That is, the stacked body 21 is not divided by the insulating layer 50. The insulating film 30B is provided between the linking portion 20BB and one of the electrode layer 22C and the electrode layer 22B.

The channel body layer 20B includes a pair of portions 20BA that extend in the Z-direction and a portion 20BB that is connected to the portions 20BA to each other. The insulating film 30B is provided between one of the multiple electrode layers 22A to 22D and the portions 20BA. That is, transistors are formed of the one of the multiple electrode layers 22A to 22D, the insulating film 30B, and the portions 20BA of the channel body layer 20B. The insulating film 30B is provided between the portion 20BB and one of the multiple electrode layers 22A to 22D. The insulating film 30B that is disposed on the portion 20BB contacts one of the electrode layers 22B,22C. The portions 20BA may be called the columnar portions; and the portion 20BB may be called the linking portion.

A gate insulator film 35 is provided between the channel body layer 20 and the selection gate electrodes 45D. A gate insulator film 36 is provided between the channel body layer 20 and the selection gate electrodes 45S.

A selection transistor STD is formed of the selection gate electrodes 45D, the channel body layer 20A, and the gate insulator film 35. A selection transistor STS is formed of the selection gate electrodes 45S, the channel body layer 20A, and the gate insulator film 36. A back gate transistor BGT is formed of the back gate 22, the channel body layer 20B, and the insulating film 30B.

A memory string MS having a U-shaped configuration is formed of the multiple memory films 30A, the selection transistor STD, the back gate transistor BGT, and the selection transistor STS connected in series by the channel body layer 20 (FIG. 2).

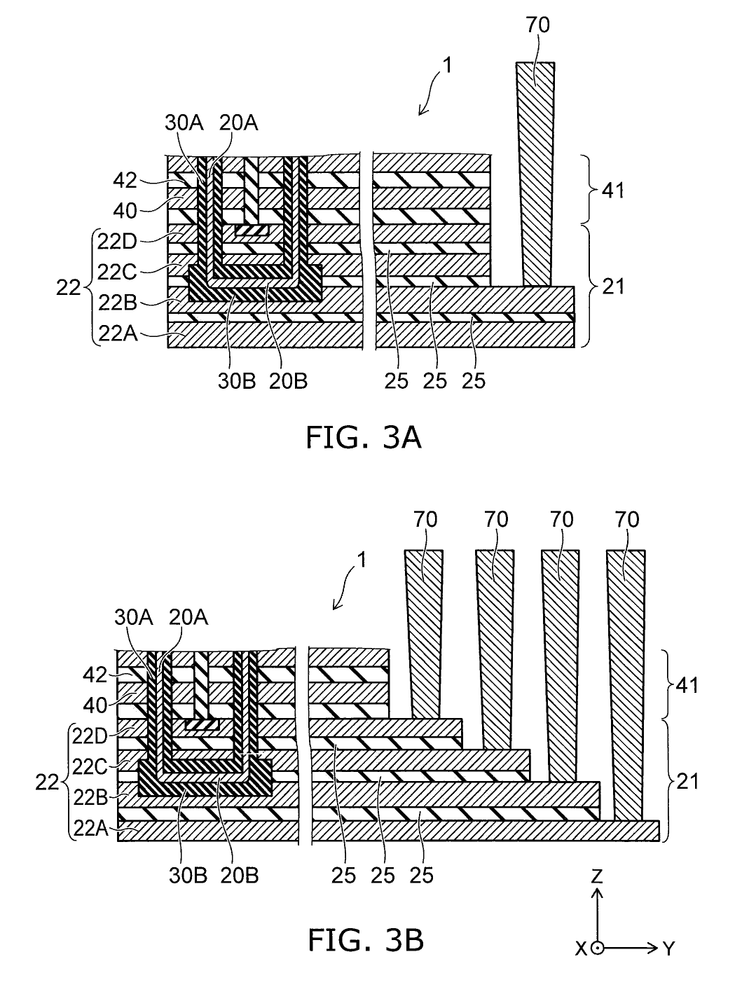

FIG. 3A and FIG. 3B are schematic cross-sectional views showing the nonvolatile semiconductor memory device according to the first embodiment.

The vicinity of the back gate 22 is shown in an enlarged state in FIG. 3A and FIG. 3B.

As shown in FIG. 3A, the electrode layer 22C is provided on the linking portion 20BB of the channel body layer 20B via the insulating film 30B. The electrode layer 22B is provided under the linking portion 20BB of the channel body layer 20B via the insulating film 30B. One of the insulating layers 25 is provided between the channel body layer 20B and the electrode layer 22C. The nonvolatile semiconductor memory device 1 includes a contact electrode 70 that reaches the stacked body 21. The contact electrode 70 extends in the Z-direction. The contact electrode includes polysilicon, tungsten, molybdenum, titanium, titanium nitride, etc.

The contact electrode 70 is connected to one of the multiple electrode layers 22A to 22D. For example, in the example of FIG. 3A, the contact electrode 70 is connected to the electrode layer 22B. Thereby, the prescribed potential can be supplied to the electrode layer 22B from the peripheral circuit via the contact electrode 70.

As shown in FIG. 3B, the contact electrodes 70 may be connected respectively to the multiple electrode layers 22A to 22D. By such a structure, potentials can be supplied independently to each electrode layer included in the back gate 22. That is, the controllability of the potential of the back gate 22 improves.

Manufacturing processes of the nonvolatile semiconductor memory device 1 according to the first embodiment will now be described.

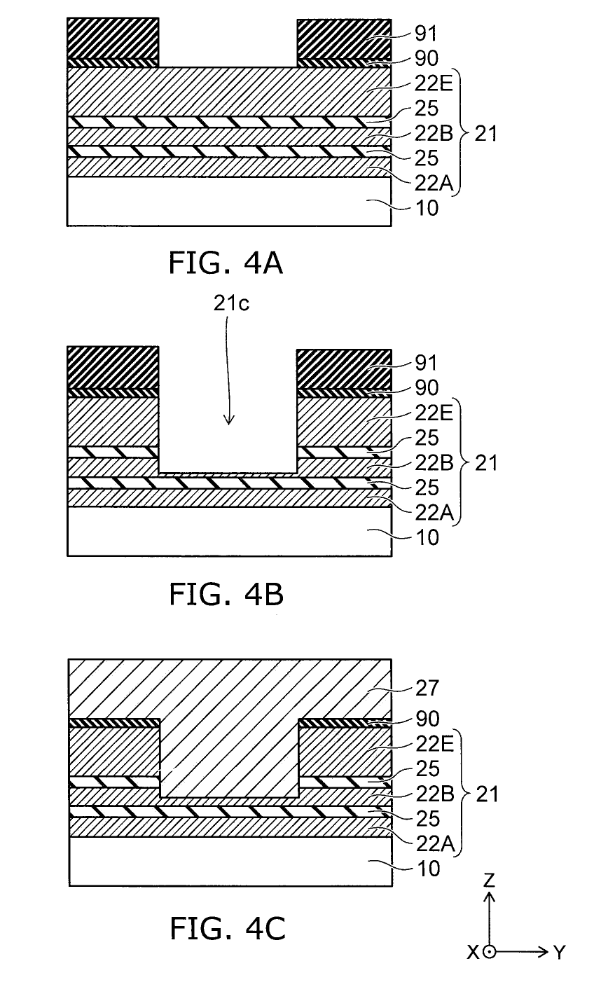

FIG. 4A to FIG. 6B are schematic cross-sectional views showing the manufacturing processes of the nonvolatile semiconductor memory device according to the first embodiment.

First, as shown in FIG. 4A, the stacked body 21 that includes the electrode layer 22A/insulating layer 25/electrode layer 22B/insulating layer 25/electrode layer 22E is formed on the foundation layer 10. Then, mask layers 90 and 91 are patterned on the stacked body 21.

Then, as shown in FIG. 4B, the stacked body 21 that is exposed from the mask layers 90 and 91 is etched by RIE (Reactive Ion Etching). Thereby, a recess 21c is made in the stacked body 21. At this stage, the etching is stopped partway through the stacked body 21 without exposing the foundation layer 10.

Then, after removing the mask layer 91 as shown in FIG. 4C, a sacrificial layer 27 is formed inside the recess 21c and on the mask layer 90. The sacrificial layer 27 includes non-doped amorphous silicon.

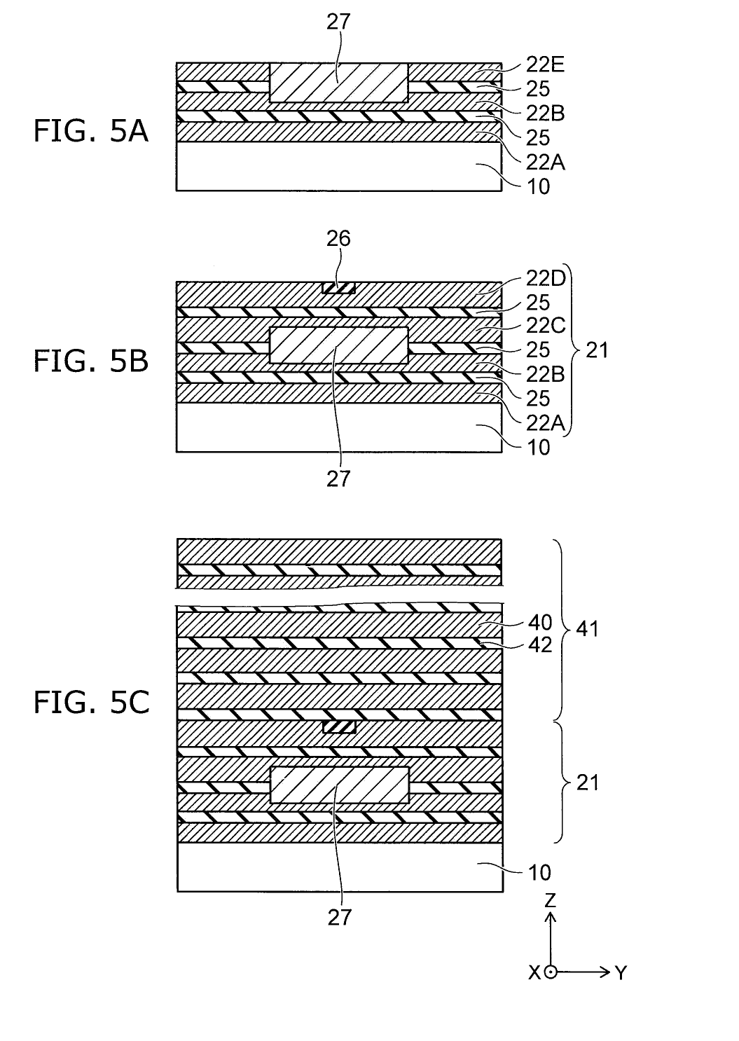

Then, as shown in FIG. 5A, the mask layer 90 is removed and the heights of the electrode layer 22E is caused to be even with the sacrificial layer 27 by a method such as RIE, CMP (Chemical Mechanical Polishing), etc.

Continuing as shown in FIG. 5B, an electrode layer having a prescribed film thickness is added onto the electrode layer 22E to form the electrode layer 22C; and the insulating layer 25 and the electrode layer 22D are formed on the electrode layer 22C. Thereby, the stacked body 21 is formed on the foundation layer 10.

The insulating layer 26 is formed above the sacrificial layer 27 as necessary. To form the insulating layer 50 described above, a trench for filling the insulating layer 50 is pre-made by RIE; and the insulating layer 26 functions as an etching stop layer in the RIE.

At this stage, the stacked body 21 that includes the sacrificial layer 27 is formed on the foundation layer 10. The stacked body 21 includes the multiple electrode layers 22A to 22D, and the insulating layers 25 that are provided in each space between the multiple electrode layers 22A to 22D. Then, as shown in FIG. 5C, the stacked body 41 is formed on the stacked body 21.

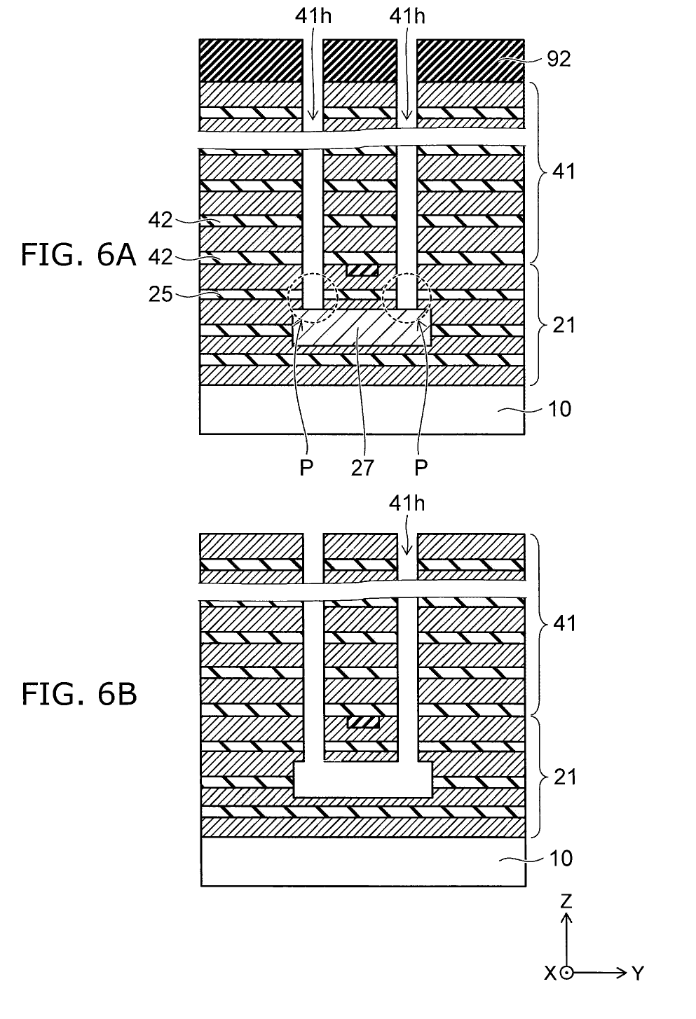

Then, as shown in FIG. 6A, a mask layer 92 is patterned on the stacked body 41. Continuing, the stacked body 41 that is exposed from the mask layer 92 and a portion of the stacked body 21 on the lower side of the stacked body 41 are etched by RIE. Thereby, a pair of holes 41h is made to pierce the stacked body 41 and portions of the stacked body 21 in the Z-direction and reach the sacrificial layer 27.

When performing RIE patterning of the portions of the stacked body 41 and the stacked body 21, at least one gas of a CFₓ-based gas, NF₃, O₂, H₂, N₂, HBr, Ar, or the like is used as the gas for etching. CF₄, CH₂F₂, C₄F₆, C₄F₈, CH₃F, etc., may be used as the CFₓ-based gas.

In addition to the CFₓ-based gas, oxygen of the desired concentration is necessary for the RIE to progress. Here, the stacked body 41 includes the insulating layers 42; and the stacked body 21 includes the insulating layers 25. Accordingly, oxygen is emitted from the insulating layers 25 and 42 when etching the insulating layers 25 and 42; and the oxygen functions as an etchant of the RIE.

Accordingly, the lower portion of the hole 41h does not easily have a tapered configuration; and the configuration of the lower portion of the hole 41h is a straight configuration or a substantially straight configuration. The oxygen is emitted from the insulating layers 25 and 42 in the etching even in the case where the number of stacks is higher for the stacked bodies 21 and 41. That is, even if the aspect ratio of the hole 41h is high, the lower portion of the hole 41h does not easily have a tapered configuration; and the configuration of the lower portion of the hole 41h is a straight configuration or a substantially straight configuration (arrow P).

When performing RIE patterning of the stacked bodies 21 and 41 shown in FIG. 6A, a gas that does not include carbon (C) may be used instead of the CFₓ-based gas.

Then, as shown in FIG. 6B, wet etching is performed to selectively remove the sacrificial layer 27. The sacrificial layer 27 is removed from the stacked body 21 through the pair of holes 41h. For example, an alkaline solution (a KOH solution, etc.) is used as the etching solution.

Here, a sufficient amount of the etching solution is supplied to the sacrificial layer 27 because the lower portions of the holes 41h have configurations that are straight configurations or substantially straight configurations. Further, the sacrificial layer 27 that is dissolved is discharged efficiently through the holes 41h. Thereby, the hole 41h is made by the space where the sacrificial layer 27 is removed communicating with the pair of holes 41h.

Subsequently, as shown in FIGS. 1A and 1B, the memory film 30A and the insulating film 30B are formed on the inner wall of the hole 41h; and continuing, the channel body layer 20A is formed with the memory film 30A interposed; and the channel body layer 20B is formed with the insulating film 30B interposed.

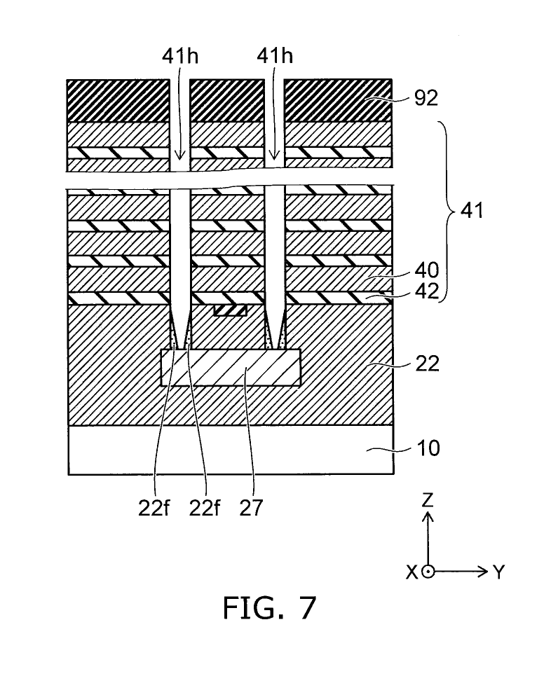

Before describing the effects of the first embodiment, a manufacturing process of a nonvolatile semiconductor memory device according to a reference example is shown in FIG. 7.

FIG. 7 is a schematic cross-sectional view showing the manufacturing process of the nonvolatile semiconductor memory device according to the first reference example.

The nonvolatile semiconductor memory device according to the first reference example includes the back gate 22. The back gate 22 is a single layer; and the material of the back gate 22 is a layer including polysilicon to which an impurity element is added. Accordingly, oxygen is not emitted from the back gate 22 in the RIE patterning of the back gate 22.

Thereby, in the RIE patterning, the components that are emitted from the back gate 22 may re-adhere at the lower portions of the holes 41h. That is, a film 22f may form at the lower portions of the holes 41h. Accordingly, the diameters of the holes 41h are narrower toward the foundation layer 10. That is, tapers are formed.

Even if it is attempted to form the channel body layer, the memory film 30A, and the insulating film 30B in such a state, the channel body layer, the memory film 30A, and the insulating film 30B are not formed with sufficient film thicknesses at the lower portions of the holes 41h and in the space where the sacrificial layer 27 is removed. That is, a channel body layer having a good configuration is not formed. As a result, characteristic degradation of the nonvolatile semiconductor memory device may occur.

Conversely, in the first embodiment as shown in FIG. 6A, the configurations of the lower portions of the holes 41h are straight configurations or substantially straight configurations. Accordingly, the channel body layer, the memory film 30A, and the insulating film 30B can be formed to have the target amounts (film thicknesses) at the lower portions of the holes 41h and in the space where the sacrificial layer 27 is removed. That is, the configuration of the channel body layer is good; and characteristic degradation of the nonvolatile semiconductor memory device does not occur easily.

Another reference example will now be described.

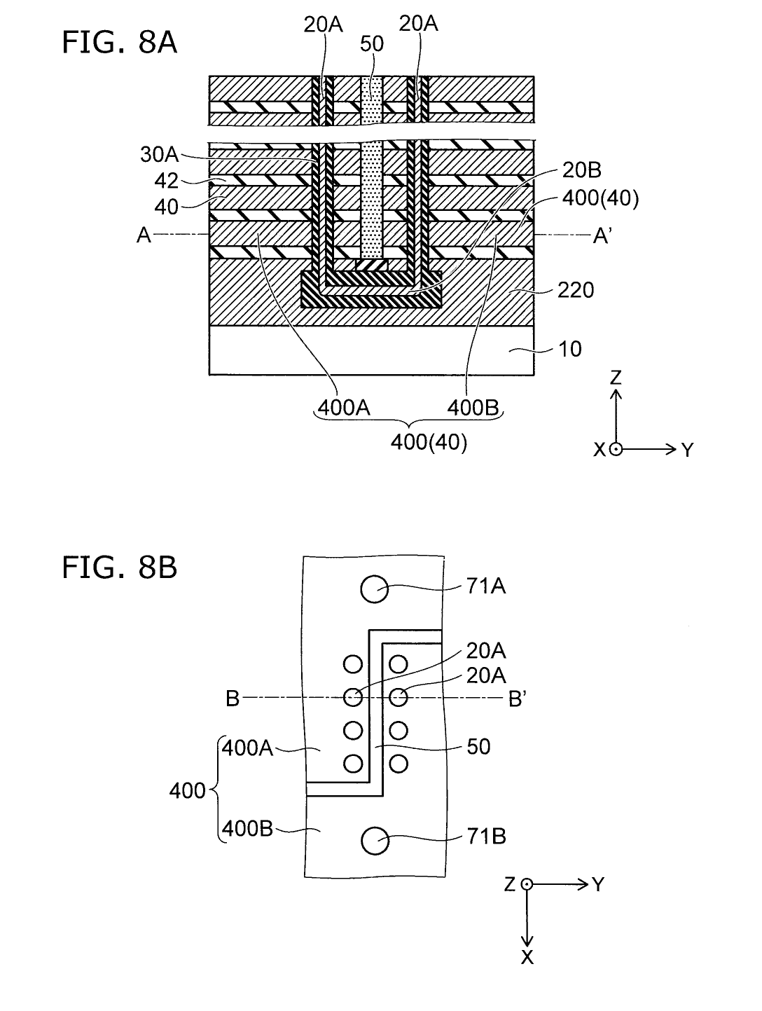

There is a structure in which the back gate 22 itself is formed to be thin as a method for suppressing the re-adhering in the RIE patterning. Such an example is shown in FIGS. 8A and 8B.

FIG. 8A is a schematic cross-sectional view showing the nonvolatile semiconductor memory device according to the second reference example; and FIG. 8B is a schematic plan view showing the nonvolatile semiconductor memory device according to the second reference example.

Here, a cross section at a position along line B-B′ of FIG. 8B is shown in FIG. 8A; and a cross section at a position along line A-A′ of FIG. 8A when viewed from the upper surface is shown in FIG. 8B.

In the second reference example, the electrode layer 40 of the lowermost layer is easily affected by the electric field from a single-layer back gate 220. Therefore, the electrode layer 40 of the lowermost layer is not used as a control gate but is used as a dummy electrode 400.

However, the dummy electrode 400 is divided by the insulating layer 50. Therefore, the dummy electrode 400 is divided in the Y-direction into an electrode layer 400A and an electrode layer 400B. Accordingly, for a contact electrode to be connected to the dummy electrode 400, it is necessary to individually provide a contact electrode 71A connected to the electrode layer 400A and a contact electrode 71B linked to the electrode layer 400B.

Conversely, the contact electrode to be connected to the dummy electrode of the nonvolatile semiconductor memory device 1 is described below.

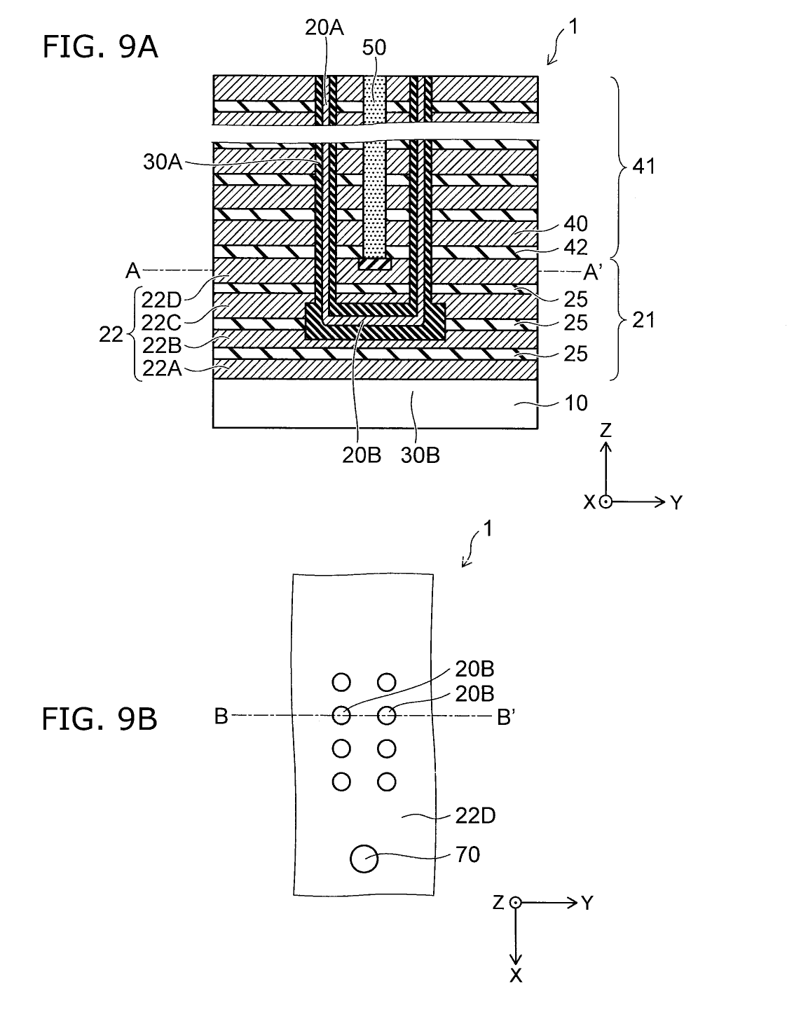

FIG. 9A is a schematic cross-sectional view showing the nonvolatile semiconductor memory device according to the first embodiment; and FIG. 9B is a schematic plan view showing the nonvolatile semiconductor memory device according to the first embodiment.

Here, the cross section at the position along line B-B′ of FIG. 9B is shown in FIG. 9A; and the cross section at the position along line A-A′ of FIG. 9A when viewed from the upper surface is shown in FIG. 9B.

In the first embodiment, the electrode layer 22D of the uppermost layer of the back gate 22 can be used as the dummy electrode. That is, dummy transistors are formed of the electrode layer 22D, the insulating film 30B, and the portions 20BA of the channel body layer 20B. Also, the back gate 22 is not divided in the Y-direction by the insulating layer 50. Therefore, the contact electrode 70 suffices as the contact electrode to be connected to the dummy electrode.

### Second Embodiment

Over-etching is performed in the process of making the holes 41h described above (FIG. 6A) so that the holes 41h may extend below the sacrificial layer 27.

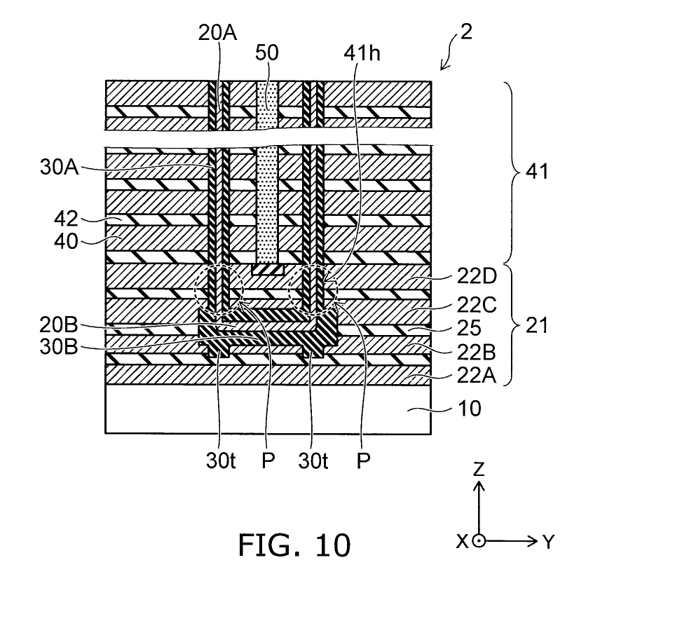

FIG. 10 is a schematic cross-sectional view showing the nonvolatile semiconductor memory device according to the second embodiment.

In the nonvolatile semiconductor memory device 2, protruding portions 30t are provided to extend from the insulating film 30B on the lower side toward the foundation layer 10. The existence of such protruding portions 30t is caused by the holes 41h extending below the sacrificial layer 27 in the over-etching described above and the insulating film 30B being formed in the portions where the holes 41h extend through.

In the nonvolatile semiconductor memory device 2, the over-etching described above is performed in the process of making the holes 41h. Therefore, the configurations of the holes 41h at the portions illustrated by arrows P are straighter than those of the nonvolatile semiconductor memory device 1.

Although a form in which the pair of channel body layers 20A and the channel body layer 20B are formed as one body in a U-shaped configuration is illustrated in the embodiments recited above, the embodiments are not limited to such a form. For example, the channel body layer 20B may be provided at the lower ends of two or more multiple channel body layers and may be electrically connected commonly to the multiple channel body layers.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device, comprising:
a stacked body provided on a foundation layer, the stacked body including electrode layers stacked alternately with first insulating layers;
first semiconductor members extending in a stacking direction of the stacked body, the first semiconductor members being provided in the stacked body;
a second semiconductor member provided under the first semiconductor members, the second semiconductor member including first portions extending in the stacking direction and a second portion extending in a direction crossing the stacking direction, the first portions and the second portion being provided in the stacked body, the second semiconductor member being connected commonly to lower ends of the first semiconductor members;
a memory film provided between a first electrode layer of the electrode layers and one of the first semiconductor members; and
an insulating film provided between the second semiconductor member and the stacked body,
a second electrode layer of the electrode layers being provided on an upper surface of the second portion of the second semiconductor member via the insulating film,
a third electrode layer of the electrode layers being provided under a lower surface of the second portion of the second semiconductor member via the insulating film.

2. The device according to claim 1, further comprising a third insulating layer extending in the stacking direction between a pair of the first semiconductor members,
a portion of the second electrode layer being provided between the third insulating layer and the second portion of the second semiconductor member.

3. The device according to claim 2, wherein the third insulating layer is not in contact with the second semiconductor member.

4. The device according to claim 2, further comprising a fourth insulating layer under the third insulating layer, the fourth insulating layer being in contact with the third insulating layer.

5. The device according to claim 4, further comprising a fourth electrode layer of the electrode layers being provided above the third electrode layer, the fourth insulating layer being provided in the fourth electrode layer.

6. The device according to claim 1, wherein
the insulating film provided on the foundation layer side includes a protruding portion extending toward the foundation layer side, and
the protruding portion is positioned under the first portion of the second semiconductor member.

7. The device according to claim 1, further comprising a contact electrode extending in the stacking direction,
the contact electrode being connected to the second electrode layer contacting the insulating film.

8. The device according to claim 1, further comprising contact electrodes extending in the stacking direction,
the contact electrodes being connected respectively to the second electrode layer and the third electrode layer.

9. The device according to claim 1, wherein the first semiconductor member and the second semiconductor member include the same material.

10. The device according to claim 1, wherein the first electrode layer, the second electrode layer, and the third electrode layer include the same material.

11. A method for manufacturing a nonvolatile semiconductor memory device, comprising:
forming a second stacked body on a foundation layer, the second stacked body including second electrode layers and a second insulating layer, the second insulating layer being provided between the second electrode layers, a sacrificial layer being provided in the second stacked body;
forming a first stacked body on the second stacked body, the first stacked body including first electrode layers stacked alternately with first insulating layers;
forming a pair of holes extending in a stacking direction of the first stacked body to reach the sacrificial layer;
forming a hole by linking the pair of holes by removing the sacrificial layer through the pair of holes; and
forming a memory film and a semiconductor member on an inner wall of the hole, the memory film being provided between the semiconductor member and the inner wall.

12. The method according to claim 11, wherein the first stacked body and the second stacked body are etched using the same etching gas.

13. The method according to claim 11, wherein the pair of holes are made to extend below the sacrificial layer.

14. The method according to claim 11, wherein the first insulating layers and the second insulating layer include the same material.

15. The method according to claim 11, wherein the first insulating layers and the second insulating layer include oxygen.

16. The method according to claim 11, wherein the first electrode layers and the plurality of second electrode layers include the same material.
